(19) United States
(12) Patent Application Publication
(10) Pub. No.: US 2025/0022751 A1
(43) Pub. Date: Jan. 16, 2025

(54) GRADIENT LINER IN METAL FILL

(71) Applicant: Lam Research Corporation, Fremont, CA (US)

(72) Inventors: Sang-Hyeob LEE, Fremont, CA (US); Anand CHANDRASHEKAR, Fremont, CA (US); Kaihan Abidi ASHTIANI, Cupertino, CA (US); Patrick August VAN CLEEMPUT, Duvall, WA (US); Joshua COLLINS, Sebastopol, CA (US); Lawrence SCHLOSS, Palo Alto, CA (US); Sanjay GOPINATH, Fremont, CA (US); Juwen GAO, San Jose, CA (US)

(21) Appl. No.: 18/714,550

(22) PCT Filed: Nov. 30, 2022
(86) PCT No.: PCT/US2022/080610

§ 371 Date: May 29, 2024

Related U.S. Application Data
(60) Provisional application No. 63/284,586, filed on Nov. 30, 2021.

(51) Int. Cl. H01L 21/768

(52) U.S. Cl. CPC H01L 21/76879; H01L 21/76844; H01L 21/76856; H01L 21/76876

(57) ABSTRACT

Methods of filling a features of partially fabricated semiconductor substrates with metal include depositing a gradient metal nitride layer in the feature. The gradient metal nitride layer decreases in thickness and/or nitrogen concentration with feature depth. At the top of the feature, the gradient metal nitride layer can serve as an adhesion layer during a subsequent planarization. Because the gradient metal nitride layer deceases in thickness and/or nitrogen concentration further into the feature, it occupies less volume in the mid-section and bottom section of the feature. This improves resistivity in the feature. The feature is filled with metal.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

In semiconductor fabrication, features such as lines and vias may be filled with conductive materials such as tungsten (W). As semiconductor devices scale down to the 10 nm node and lower, line and via contact resistance increase rapidly in metal interconnects. This is due to the reduction in current-carrying cross-section, increase in electron scattering, and the challenges of filling narrow features with metal.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided are methods of filling features with metal films. Applications include sub-10 nm node middle of line (MOL) and back end of line (BEOL) logic and memory interconnects. According to various embodiments, a gradient metal nitride layer is deposited in a feature. The gradient metal nitride layer decreases in thickness and/or nitrogen concentration with feature depth. At the top of the feature, the gradient metal nitride layer can serve as an adhesion layer during a subsequent planarization. Because the gradient metal nitride layer deceases in thickness and/or nitrogen concentration further into the feature, it occupies less volume in the mid-section and bottom section of the feature. This improves resistivity in the feature.

In some embodiments, the gradient nitride layer has a higher nitrogen concentration near the feature opening than further in the feature. The gradient nitride layer at the bottom section of the feature and/or at the mid-section of the feature is metal-rich. In some embodiments, the metal-rich portions of the gradient metal nitride layer serve as a nucleation layer for subsequent bulk metal deposition. This can allow bulk metal deposition in the feature without intervening nucleation layer deposition.

One aspect of the disclosure relates to a method including: providing a substrate including a feature having a feature opening, a feature bottom and feature sidewalls; and non-conformally depositing a metal nitride layer in the feature such that the metal nitride layer lines at least part of the feature sidewalls. The metal nitride layer decreases in thickness and/or nitrogen concentration along the feature sidewalls as it extends from the feature opening towards the feature bottom.

In some embodiments, the method further includes, after depositing the metal nitride layer, depositing a metal nucleation layer in the feature. In some such embodiments, the method further includes non-conformally treating the metal nucleation layer to inhibit metal nucleation. Metal nucleation on the feature sidewalls is inhibited to greater extent near the feature opening than near the feature bottom. In some embodiments, the method further includes depositing a bulk metal layer on the metal nucleation layer.

In some embodiments, the metal is tungsten or molybdenum. In some embodiments, conformally depositing the metal nitride layer in the feature includes delivering pulses of ammonia (NH₃) and a metal-containing precursor to a chamber housing the substrate. In some such embodiments, non-conformally depositing the metal nitride in the feature further includes delivering pulses of diborane (B₂H₆) to the chamber.

In some embodiments, non-conformally depositing the metal nitride in the feature includes delivering pulses of a metal-containing precursor and plasma-activated nitrogen species to a chamber housing the substrate. In some such embodiments, non-conformally depositing the metal nitride in the feature includes delivering pulses of diborane (B₂H₆) to the chamber.

In some embodiments, the thickness of the metal nitride layer on the sidewall near the feature opening is at least twice the thickness of the metal nitride layer on the sidewall at a point halfway down the sidewall between the feature opening and the feature bottom.

In some embodiments, a thickness of the metal nitride layer at its thickest point is between 20 and 100 angstroms.

In some such embodiments, thickness of the second metal nitride layer at its thickest point is less than 10 angstroms.

In some embodiments, the method further includes non-conformally treating the metal nitride barrier layer to inhibit metal nucleation such that metal nucleation is inhibited to a greater extent near the feature opening than further in the feature.

In some such embodiments, non-conformal treatment forms a second metal nitride layer. In some such embodiments, the second metal nitride layer decreases in amount of nitride as the second metal nitride layer extends from the feature opening towards the feature bottom and the amount of nitride in the second metal nitride layer is less than the amount of nitride in the metal nitride barrier layer.

In some embodiments, the method further includes depositing a bulk metal layer in the feature including directly on a metal nitride layer.

In some such embodiments, non-conformally treating the metal nitride barrier layer to inhibit metal nucleation includes delivering pulses of ammonia and a metal-containing precursor to the chamber. In some such embodiments, non-conformally treating the metal nitride barrier layer in the feature further includes delivering pulses of diborane to the chamber.

In some embodiments, a ratio of ammonia to the metal-containing precursor is higher in the deposition of the metal nitride barrier layer than a ratio of ammonia to the metal-containing precursor in the non-conformal treatment of the metal nitride barrier layer.

In some embodiments, non-conformally depositing the metal nitride barrier layer in the feature includes delivering pulses of a metal-containing precursor and a plasma-activated nitrogen species to a chamber housing the substrate.

In some embodiments, non-conformally depositing the metal nitride barrier layer in the feature further includes delivering pulses of diborane to the chamber.

In some embodiments, non-conformally treating the metal nitride barrier layer to inhibit metal nucleation includes delivering pulses of a metal-containing precursor and a plasma-activated nitrogen species to the chamber.

Another aspect of the disclosure relates to a method including providing a feature; performing a first operation of exposing the feature to pulses of a metal precursor, a boron-containing reducing agent, and a nitrogen-containing compound; performing a second operation of exposing the feature to pulses of a metal precursor, a boron-containing reducing agent, and a nitrogen-containing compound, wherein the amount of nitrogen is higher in the first operation than the second operation; and after the first operation and the second operation, exposing the feature to the metal precursor and hydrogen.

These and other aspects are discussed further below with reference to the drawings.

### BRIEF DESCRIPTION OF DRAWINGS

FIGS. 1 and 3 are flow diagrams showing certain operations in methods according to various embodiments.

FIGS. 2 and 4 are schematic diagrams showing cross-sectional depictions of features during fill processes according to various embodiments.

FIGS. 5 and 6 show examples of apparatus that may be used to perform the methods described herein.

### DESCRIPTION

Provided are methods of filling features with metal films. Applications include sub-10 nm node middle of line (MOL) and back end of line (BEOL) logic and memory interconnects. According to various embodiments, a gradient metal nitride layer is deposited in a feature. The gradient metal nitride layer decreases in thickness and/or nitrogen concentration with feature depth. At the top of the feature, the gradient metal nitride layer can serve as an adhesion layer during a subsequent planarization. Because the gradient metal nitride layer deceases in thickness and/or nitrogen concentration further into the feature, it occupies less volume in the mid-section and bottom section of the feature. This improves resistivity in the feature.

In some embodiments, the gradient nitride layer has a higher nitrogen concentration near the feature open at the top of the feature than further in the feature. The bottom section of the feature and/or the mid-section of the feature is metal-rich. In some embodiments, the metal-rich portions of the gradient metal nitride layer serve as a nucleation layer for subsequent bulk metal deposition. This allows bulk metal deposition in the feature without intervening nucleation layer deposition.

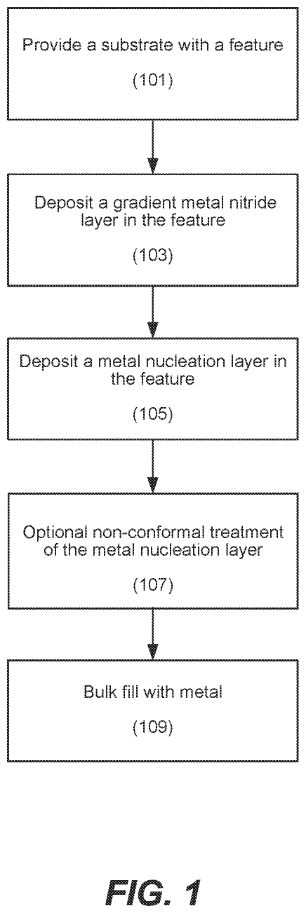

FIG. 1 is a process flow diagram illustrating a method to fill a feature having a gradient metal nitride layer with a metal. The method begins by providing a substrate including a feature in which the gradient metal nitride layer is to be deposited in operation 101. The substrate may be provided to a semiconductor processing tool. The feature may be a trench or via that is formed in a dielectric layer. Examples of dielectric materials include oxides, such as silicon oxide (SiO₂) and aluminum oxide (Al₂O₃); nitrides, such as silicon nitride (SiN); carbides, such as nitrogen-doped silicon carbide (NDC) and oxygen-doped silicon carbide (ODC); and low k dielectrics, such as carbon-doped SiO₂. The metal may be deposited in the feature to make electrical contact to an underlying layer. Examples of underlying layers include metals, metal silicides, and semiconductors. Examples of metals include Co, Ru, copper (Cu), W, Mo, nickel (Ni), iridium (Ir), rhodium (Rh), tantalum (Ta), and Ti. Examples of metal silicides include TiSiₓ, nickel silicide (NiSiₓ), molybdenum silicide (MoSiₓ), cobalt silicide (CoSiₓ), platinum silicide (PtSiₓ), ruthenium silicide (RuSiₓ), and nickel platinum silicide (NiPt_{y}Siₓ). Examples of semiconductors include silicon (Si), silicon germanium (SiGe), and gallium arsenide (GaAs) with or without semiconductor dopants such as carbon (C), arsenic (As), boron (B), phosphorus (P), tin (Sn), and antimony (Sb).

The feature generally has sidewall surfaces and a bottom surface. In some embodiments, the sidewall surfaces may be the same material as the bottom surface. In some embodiments, the sidewall surfaces may be a different material than the material of the bottom surface. For example, the bottom surface may be a metal silicide and the sidewall surface may be a silicon oxide, such as SiO₂.

Once the substrate is provided, an initial metal nitride layer is deposited in the feature in operation 103. The initial metal nitride layer is a gradient layer and may be referred to as a gradient metal nitride layer. A gradient layer is a layer that changes in thickness and/or composition with feature depth. In some embodiments, a gradient metal nitride layer as described herein gradually becomes thinner and/or decreases in nitrogen with increasing feature depth. For example, a gradient layer may be thickest at the sidewalls near the opening of the feature and decrease in thickness as it moves down the sidewall and toward the bottom of the feature. This is discussed in more detail further below.

The operation 103 may be a plasma operation or a thermal, non-plasma operation. The gradient metal nitride layer may be deposited by an atomic layer deposition (ALD) method. ALD is a surface-mediated deposition technique in which doses of a reactants are sequentially introduced into a deposition chamber.

In some embodiments, a metal nitride liner is deposited by reacting a metal precursor and a reducing agent to form a metal layer and then nitriding the metal layer to form a metal nitride. For example, tungsten nitride may be depositing with an ALD sequence using diborane (B₂H₆) as the reducing agent, tungsten hexafluoride (WF₆) as a tungsten precursor, and ammonia (NH₃) as a nitriding agent. The NH₃ may or may not be co-flowed with WF₆. In one such example, a sequence may be B₂H₆/WF₆/NH₃+WF₆, with “/” indicating separate doses. The doses may be separated by a purge. In some embodiments, the B₂H₆ and WF₆ doses are separated by a purge with no purge used between WF₆ and NH₃+WF₆. Multiple cycles of the sequence may be used to deposit the gradient metal nitride layer.

In some embodiments, WF₆ is reacted with NH₃ with no additional reducing agent used. In one example, a sequence of WF₆/NH₃ is used with “/” indicating separate doses. The doses may be separated by a purge.

In alternate embodiments, a plasma-based nitridation may be used with nitrogen radicals and/or ionic species used as the nitridation agent. A remote or in-situ plasma generated from a nitrogen-containing gas such as N₂ may be used. A plasma generated from N₂ is referred to as an N₂ plasma. In one example, a deposition sequence may be B₂H₆/WF₆/N₂ plasma. The doses may be separated by a purge. Other metal containing precursors may be used for deposition of tungsten or other metals such as molybdenum. Multiple cycles of the sequence may be used to deposit the gradient metal nitride layer. Further discussion of forming metal nitride layers is provided below.

In some embodiments, the gradient metal nitride layer may have a thickness of 20-100 or 40-60 Angstroms at its thickest point. Generally, the thickest part of the layer on the sidewall is at or near the feature opening. The thickness of the layer may decrease as the layer goes further into the feature.

In some embodiments depositing a gradient metal layer involves using mass transport limiting conditions. Mass transport limiting conditions may be characterized, in part, by overall reactant concentrations. In certain implementations, a concentration is less inside the feature than near its opening resulting in a higher deposition rate near the opening than inside. This in turn leads to selective deposition near the feature opening. Mass transport limiting process conditions may be achieved by supplying limited amounts of reactants into the processing chamber while maintaining relative high deposition rates near the feature opening to consume reactants as they diffuse into the feature. To supply limited amounts of reactants, low reactant gas flow rates and/or dose time relative to the feature profile and dimensions, may be used.

In certain implementation, a concentration gradient is substantial, which may be caused by relatively high deposition kinetics and relatively low reactant supply. In certain implementations, a deposition rate near the opening may also be mass transport limited, though this condition is not required to achieve selective deposition. Flow rates and dose time for achieving mass transport limiting conditions may depend on the particular apparatus used and the feature profile and dimensions being filled.

After the gradient metal nitride layer is deposition, a metal nucleation layer is deposited in operation 105. A nucleation layer is a thin layer that facilitates subsequent deposition of bulk metal material thereon. In nucleation layer deposition, pulses of a reducing agent, optional purge gases, and a metal-containing precursor may be sequentially injected into and purged from the reaction chamber in an ALD sequence. Nucleation layer thickness can depend on the nucleation layer deposition method as well as the desired quality of bulk deposition. In general, nucleation layer thickness is sufficient to support high quality, uniform bulk deposition. Examples may range from 10 Å-100 Å. The nucleation layer is generally conformal to the feature, following the underlying feature with uniform thickness. Further description of depositing a nucleation layer is provided below.

After the metal nucleation layer is deposited, an optional non-conformal treatment of the metal nucleation layer may be performed in operation 107. Non-conformal treatment of the metal nucleation layer refers to the treatment being preferentially applied at and near the opening of the feature relative to the interior area of the feature.

In some embodiments, the non-conformal treatment inhibits metal nucleation. Nucleation inhibition inhibits subsequent metal nucleation at the treated surfaces. It can involve one or more of: deposition of an inhibition film, reaction of treatment species with the metal film to form a compound film, and adsorption of inhibition species. During the subsequent deposition operation, there is a nucleation delay on the inhibited portions of the underlying film relative to the non- or lesser-inhibited portions. In the same or other embodiments, the non-conformal treatment can remove deposited film at the treated surfaces. This can involve reacting an etchant species with the metal film to form a gaseous byproduct that is then removed.

In some embodiments, the non-conformal treatment results in a second gradient metal nitride layer deposited in the feature. The second metal nitride layer has a greater thickness at the feature opening relative to the thickness of the layer lower along the sidewall of the feature. At its thickest point, the second gradient metal nitride layer may be less than 15 angstroms. The second gradient metal nitride layer may have a higher concentration of nitrogen compared to the initial gradient metal nitride layer deposited in operation 103.

The non-conformal treatment may be a plasma or a thermal operation.

In the example of tungsten as a metal nucleation layer, pulses of ammonia (NH₃) may be used to non-conformally treat the W nucleation layer. Nitrogen-containing chemistry without halogens may be used to inhibit or delay growth of W on the W nucleation layer. Other gases such as nitrogen trifluoride (NF₃) may be used for treating the W nucleation layer. Treatment by NF₃ both inhibits tungsten nucleation and etches deposited tungsten from the treated surfaces. Nitrogen acts as an inhibition species and fluorine act as an etchant. Still further, a plasma treatment using a plasma generated from N₂ may be used to inhibit metal nucleation. Further description of inhibition treatments is provided below.

In some embodiments, operation 107 may use a sequence such as WF₆/NH₃+WF₆ or WF₆/N₂ plasma with “/” indicating reactant pulses as above. The pulses may be separated by a purge. In some embodiments, WF₆ and NH₃+WF₆ is not separated by a purge. Multiple cycles of the sequence may be used to deposit the gradient metal nitride layer. In some embodiments, operation 107 may involve exposure to NH₃ (with or without a metal precursor) or exposure to a nitrogen-containing plasma, without additional reducing agent or metal precursor doses. The exposures may be continuous flow or pulsed.

In operation 109, a bulk fill with metal is performed. Bulk deposition may involve an ALD process with a metal precursor and a reducing agent are sequentially injected into and purged from a reaction chamber. Hydrogen may be used as the reducing agent in place of a strong reducing agent such as diborane that may be used in nucleation layer deposition. By using hydrogen as the reducing agent, the bulk fill may deposit more quickly and has a lower resistivity than fills using stronger reducing agents, such as diborane.

The metal bulk deposition may also occur by a chemical vapor deposition (CVD) in which the metal-containing precursor and the reducing agent are flowed into a deposition chamber to deposit a bulk fill layer in the feature. An inert gas may be used to deliver one or more of the reactant streams, which may or may not be pre-mixed. Unlike ALD processes, the CVD process generally involves flowing the reactants continuously until the desired amount is deposited. In certain implementations, the CVD operation may take place in multiple stages, with multiple periods of continuous and simultaneous flow of reactants separated by periods of one or more reactant flows diverted.

In some embodiments, the metal is tungsten (W). In an ALD process to bulk fill the feature with W, a W precursor is pulsed. After the W precursor is pulsed, an optional purge may occur. Argon or any inert gas may be used to purge the chamber of any unadsorbed precursor. The substrate is exposed to a co-reactant which may be a reducing agent to reduce the W precursor or other co-reactant to react with the W precursor to form elemental W. The reactant may be a hydrogen-containing reactant. In some embodiments, the hydrogen-containing reactant may be thermal (non-plasma) hydrogen (H₂). For plasma-based process, a remote or in-situ plasma generated from H₂ may be used. An optional purge may be performed. The operations may be repeated until the film is fully grown.

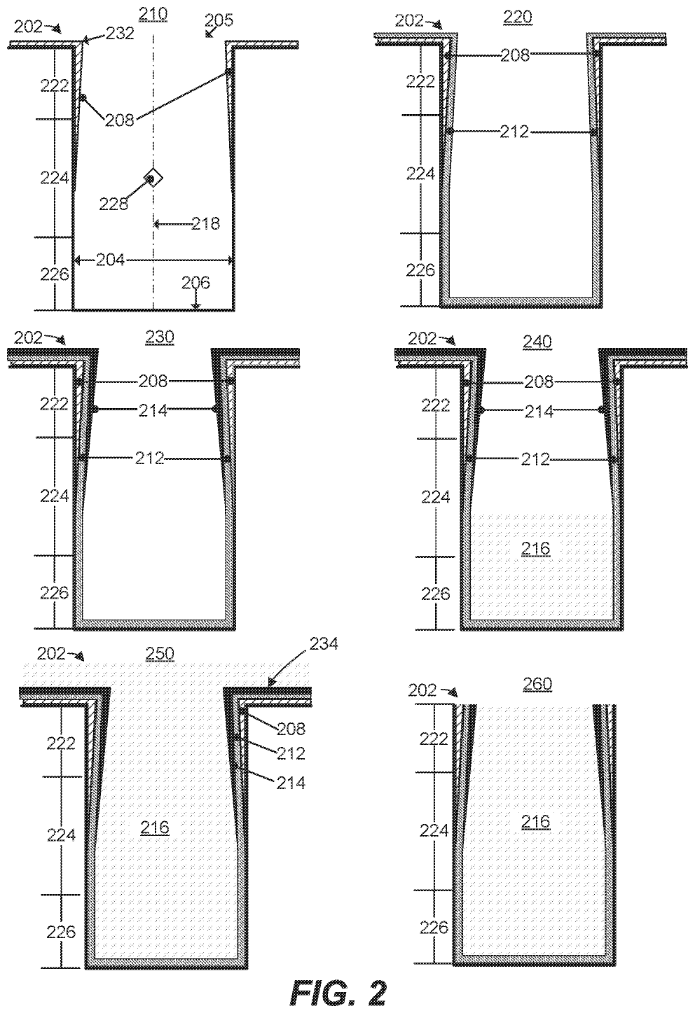

FIG. 2 shows examples of a feature after certain operations of embodiments of the method in FIG. 1. At 210, an example patterned feature 202 is shown after the initial gradient metal nitride layer 208 is deposited in the feature in operation 103. The patterned feature 202 may be, for example, an etched feature. The patterned feature 202 includes a feature opening 205, a bottom surface 206, and sidewall surfaces 204, which may be oxide or nitride.

The gradient metal nitride layer 208 has a larger thickness on the sidewall near the feature opening 222 relative to its thickness further in the feature, such on the sidewall in a mid-section 224 of the feature. In some embodiments, a gradient metal nitride layer may not extend to a bottom portion 226 of the feature. In other embodiments, it may extend to the bottom portion 226 of the material. In these embodiments, the gradient layer has material with the largest thickness along the sidewall near the feature opening 222 and has material decreasing in thickness as the material nears the bottom surface 206, such that the material thickness of the material along the sidewall in the mid-section 224 of the feature is thicker than the thickness of the material along the sidewall 204 in the bottom portion 226 of the feature. For purposes of this document, the term “mid-section 224 of the feature” represents a middle portion of the feature located about the middle point 228 of the feature along an axis 218 of the feature, e.g., an area between about 25% and 75% of the distance or, in certain embodiments, between about 40% and 60% of the distance along the feature's depth measured from the feature's opening. The term “bottom portion 226 of the feature” represents an end portion of the feature located between about 75% and 100% of the distance along the axis 218 of the feature as measured from the feature opening 205. The term “near the opening of the feature 222” or “near the feature's opening” represents a top portion of the feature located within 25% or, in some embodiments, within 10% of the edge 232 of the opening or other element representative of the edge of the opening.

In the example shown at 210, the gradient metal nitride layer 208 is thickest along the sidewall surface 204 near the feature opening 222. As the gradient metal nitride layer 208 moves down the sidewall surface 204, its thickness reduces. In the embodiment shown, the gradient metal nitride layer 208 ends in the mid-section 224 of the feature. In some embodiments, the metal nitride layer 208 may extend along the sidewall surface 204 to the bottom portion 226 of the feature. In some embodiments, the metal nitride layer 208 may extend along the sidewall surface 204 to the bottom surface 206 of the feature. The thickness of the metal nitride layer 208 decreases gradually as the metal nitride layers moves further down into the feature 202.

In some embodiments, as shown at 210, the thickness of the metal nitride layer 208 has a uniform slope. In some embodiments, the thickness may have a varying slope. For example, the thickness of the slope may reduce at a first rate near the feature opening 222 and may reduce at a second rate different from the first rate in the mid-section 224 of the feature. In general, the decrease in thickness may be uniform or non-uniform and may or may not include regions of constant thickness.

At 220, the patterned feature 202 is shown after a nucleation layer 212 is deposited into the feature. In the embodiment shown, the nucleation layer 212 is conformally deposited into the feature. The nucleation layer 212 is deposited over the metal nitride layer 208, directly on the dielectric surface along the sidewall surfaces 204, and the bottom surface 206. The nucleation layer has a generally uniform thickness in the example of FIG. 2. In other embodiments, the thickness may vary.

At 230, the patterned feature 202 is shown after an optional treatment is performed on the nucleation layer 212. The optional treatment exposes the nucleation layer 212 to an inhibition chemistry to inhibit or delay growth along the treated surfaces during bulk metal deposition. In the embodiment shown, the optional treatment deposits a second metal nitride layer 214. The second metal nitride layer 214 is a gradient layer, having the thickness of the second metal nitride layer 214 at its thickest along the sidewall surface 204 near the feature opening 222. As the second metal nitride layer 214 goes further down in the feature the thickness of the second metal layer 214 reduces. Shown at 230, the thickness of the second metal nitride layer 214 decreases at a uniform rate. In some embodiments, the thickness of the second metal nitride layer 214 may decrease at varying rate. In the embodiment shown, the second metal nitride layer 214 ends in the mid-section 224 of the feature. In some embodiments, the second metal nitride layer 214 may extend along the sidewall surface 204 to the bottom portion 226 of the feature.

Unlike the gradient metal layer 208, the second metal nitride layer 214 may be sacrificial and may be removed during deposition of the subsequent bulk fill. In some embodiments, it is thin. For example, at its thickest point it may be only 5 Angstroms thick. In many embodiments, it is less than 10 Angstroms thick at the feature top.

In some embodiments, operation 107 of FIG. 1 is better characterized as a surface treatment rather than forming a second metal nitride layer. For example, inhibition species may be physisorbed onto the underlying metal nucleation layer. In such embodiments, the treatment profile may be such that the surface effect is stronger along the sidewall surface 204 near the feature opening 222 and decreases as the depth increases. However, in some embodiments, it forms a nitride layer on the nucleation surface (e.g., WN+BN or MoN) or nitrogen is otherwise incorporated into the nucleation lattice.

The patterned feature 202 is shown after the metal bulk fill begins in 240. The bulk metal 216 is preferentially deposited on the least inhibited portions of the nucleation layer 212, such as on the bottom surface 206 and in the bottom portion 226 of the feature. As shown, the feature fills from the bottom surface 206. The bottom half of the feature is filled with metal.

The patterned feature 202 shown at 250 is after the metal bulk fill step is completed. The bulk metal 216 fills the entire feature 202 and includes an overburden. In the example shown, the bulk metal 216 is deposited on field regions 234 that surround the feature 202 on the substrate surface.

At 260, an example patterned feature 202 is shown after the feature is planarized. The planarization step may remove materials outside the feature 202, including the gradient metal nitride layer 208, the nucleation layer 212, the second gradient metal nitride layer 214, and the bulk metal 216. The planarization step may be, for example, a chemical mechanical planarization (CMP). The gradient metal nitride layer 208 acts as an adhesion layer, preventing peeling or popping during CMP. Since the gradient metal nitride layer 208 does not occupy feature volume at the middle and bottom of the feature, contact or line resistance is improved.

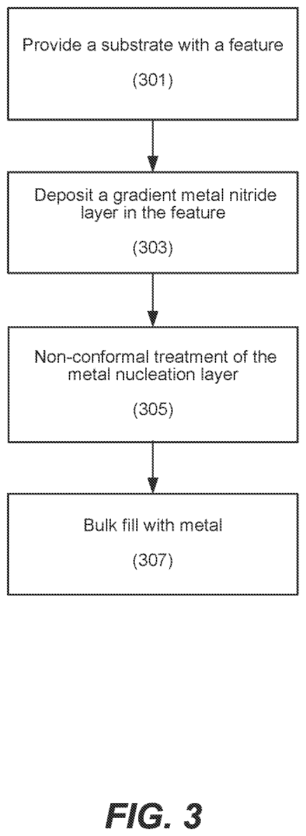

FIG. 3 is a second process flow diagram illustrating a method to fill a feature having a gradient metal nitride layer with a metal. The method begins by providing a substrate including a feature in which the metal nitride layer is to be deposited in operation 301. The substrate may be provided to a semiconductor processing tool. The feature may be a trench or via that is formed in a dielectric layer. Example of dielectric materials are similar to those discussed above in FIG. 1. The metal may be deposited in the feature to make electrical contact to an underlying layer. Examples of underlying layers are similar to those discussed above in FIG. 1.

The feature generally has sidewall surfaces and a bottom surface. In some embodiments, the sidewall surfaces may be the same material as the bottom surface. For example, in some embodiments, the sidewall surfaces and the bottom surface are TiN. In some embodiments, the sidewall surfaces may be a different material than the material of the bottom surface. For example, the bottom surface may be a tungsten and the sidewall surface may be a silicon oxide, such as SiO₂.

Once the substrate is provided, an initial gradient metal nitride layer is deposited in the feature in operation 303. In some embodiments, the gradient metal nitride layer changes thickness with feature depth. The gradient metal nitride layer is thicker at the top of the feature near an opening of the feature and reduces in thickness as the layer goes down into the feature. In the same or other embodiments, the gradient metal nitride layer changes composition such that the amount of nitrogen relative to the metal changes with feature depth. In this case, the amount of nitrogen relative the amount of metal reduces as the metal nitride layer goes further down into the feature. In some other embodiments, the metal nitride layer has decreasing thickness and decreasing nitrogen relative to metal with feature depth.

In some embodiments, the gradient metal nitride layer may have a thickness of 20-100 or 40-60 Angstroms at its thickest point. Generally, the thickest part of the layer on the sidewall may be near the feature opening. The thickness of the layer may decrease as the layer goes further into the feature.

In some embodiments, the highest amount of nitrogen of the layer on the sidewall may be near the feature opening. The amount of nitrogen in the layer may decrease as the layer goes further into the feature.

After the gradient metal nitride layer is deposited, an optional non-conformal treatment of the initial metal nitride layer may be performed in operation 305. Non-conformal treatment of the metal nitride layer refers to the treatment being preferentially applied at and near the opening of the feature relative to the interior area of the feature. In some embodiments, the non-conformal treatment may result in a second gradient metal nitride layer deposited into the feature. Similar to the initial metal nitride layer deposited in operation 303, the second metal nitride layer may change in thickness and/or composition as the layer goes further down into the feature. In some embodiments, the second metal nitride layer may change thickness with the layer having a greater thickness at the feature opening relative to the thickness of the metal nitride layer lower along the sidewall of the feature. At its thickest point, the thickness of the second metal nitride may be less than 15 angstroms. In some other embodiments, the amount of nitrogen relative to the metal in the metal nitride layer may decrease as the layer goes down into the feature. The amount of nitrogen may be larger nearer the feature opening and the amount of nitrogen may reduce as the second metal nitride layer goes lower into the feature along the sidewall. In these embodiments, the thickness of the layer may either remain relatively constant or reduce in thickness as the layer goes down into the feature.

The total amount of nitrogen in the second gradient metal nitride layer may be less than the amount of nitrogen in the initial metal nitride layer. The concentration of nitrogen in the second gradient metal nitride layer may be less than the concentration of nitrogen in the initial metal nitride layer. The non-conformal treatment may be a plasma or a thermal operation.

In some embodiments, the non-conformal treatment inhibits metal nucleation. Nucleation inhibition is described above in operation 107 of FIG. 1. Further description is provided below.

In operation 307, a bulk fill with metal is performed. Bulk deposition may involve an ALD process. The metal bulk deposition may also occur by a chemical vapor deposition (CVD). Both ALD processes and CVD processes are described above in operation 109 of FIG. 1. Further description is provided below.

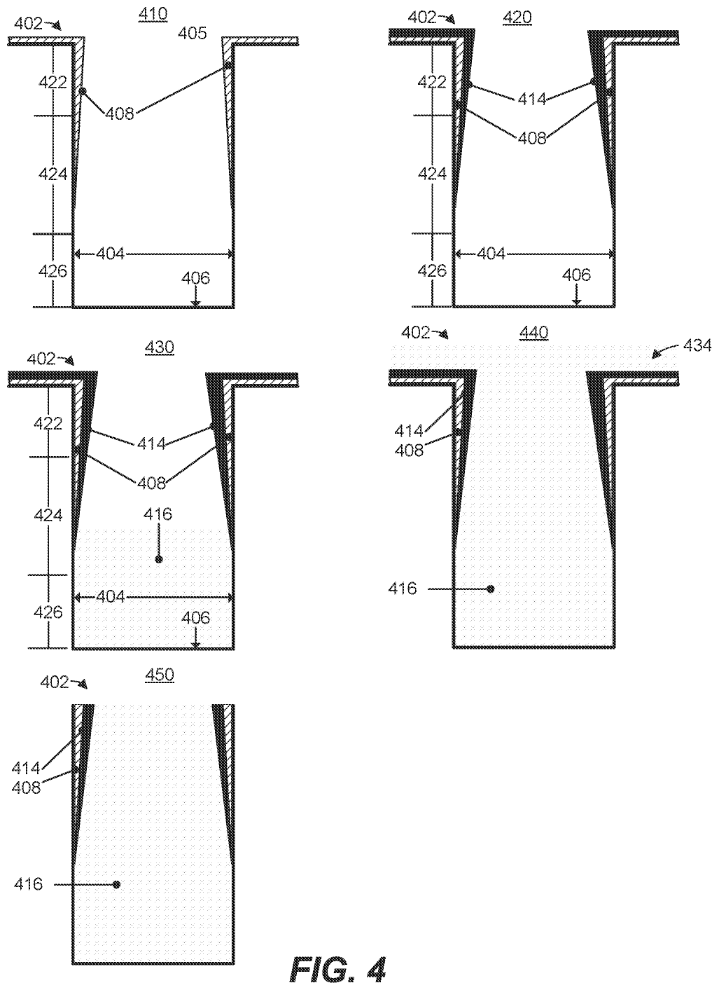

FIG. 4 show examples of a feature after certain operations of embodiments of the method in FIG. 3. At 410, an example patterned feature 402 is shown after the initial metal nitride layer 408 is deposited in the feature from operation 303 of FIG. 3. The patterned feature 402 may be, for example, an etched feature. The patterned feature 402 includes a feature opening 405, a bottom surface 406, and sidewall surfaces 404, which may be oxide or nitride.

In the example shown at 410, the metal nitride layer 408 is a gradient layer. The metal nitride layer 408 reduces in thickness as the layer moves down the feature 402. In the embodiment shown, the metal nitride layer 408 ends in a mid-section 424 of the feature. In some embodiments, the metal nitride layer 408 may extend along the sidewall surface 404 to a bottom portion 426 of the feature 402. In some embodiments, the metal nitride layer 408 may extend along the sidewall surface 404 to the bottom surface 406 of the feature 402.

The thickness of the metal nitride layer 408 decreases gradually as the metal nitride layers moves further down into the feature 402. In some embodiments, as shown at 410, the thickness of the metal nitride layer 408 has a uniform slope. In some embodiments, the thickness of the metal nitride layer 408 may have a varying slope. For example, the thickness of the slope may reduce at a first rate near the feature opening 422 and may reduce at a second rate different from the first rate in the mid-section 424 of the feature. In some other embodiments, the metal nitride layer 408 may remain the same thickness but reduce in the amount of nitrogen (relative to the metal) in the metal nitride layer 408 as it moves down the feature 402. For example, the amount of nitrogen in the metal nitride layer 408 may be greater near the feature opening 422 compared to the amount of nitrogen in the layer in the mid-section 424 of the feature. In some embodiments, the metal nitride layer 408 may reduce in thickness and reduce in amount of nitrogen as the layer moves down the feature 402.

At 420, the patterned feature 402 is shown after an optional treatment is performed on the initial metal nitride layer 408. The optional treatment exposes the initial metal nitride layer 408 to an inhibition chemistry to inhibit or delay growth along the treated surfaces during bulk metal deposition. In the embodiment shown, the optional treatment deposits a second metal nitride layer 414. The second metal nitride layer 414 is a gradient layer. In some embodiments, the second metal nitride layer 414 reduces in thickness as the second metal nitride layer goes down into the feature. In these embodiments, the thickest section of the second metal nitride layer 414 is along the sidewall surface 404 near the feature opening 422. As the second metal nitride layer 414 goes further down in the feature, the thickness of the second metal nitride layer 414 reduces. The thickest part of the second metal nitride layer 414 may be less than 15 angstroms. Shown at 430, the thickness of the second metal nitride layer 414 decreases at a uniform rate. In some embodiments, the thickness of the second metal nitride layer 414 may decrease at varying rates. In the embodiment shown, the second metal nitride layer 414 ends in the mid-section 424 of the feature. In some embodiments, the second metal nitride layer 414 may extend along the sidewall surface 404 to the bottom portion 426 of the feature. In some embodiments, the second metal nitride layer 414 may be a uniform thickness as it goes down into the feature 402. In these embodiments, the second metal nitride layer 414 changes composition as the layer goes further into the feature 402.

As discussed above, the second metal nitride layer 414 may have less nitrogen as the layer goes deeper into the feature 402. In still some other embodiments, the second metal nitride layer 414 may reduce in thickness and in amount of nitrogen as the second metal nitride layer goes down into the feature 402.

The patterned feature 402 is shown after the metal bulk fill begins in 430. The bulk metal 416 may be preferentially deposited on the non-inhibited (or less inhibited) portions of the feature 402, such as on the bottom surface 406 and in the bottom portion 426 of the feature. As shown, the feature 402 fills from the bottom surface 406 and sidewall surfaces 404 in the bottom portion 426 of the feature 402. In this example, the metal growth starts out on dielectric material. As the feature 402 starts to fill, the metal 416 fills in the bottom half of the feature.

The patterned feature 402 shown at 440 is after the metal bulk fill step is completed. The bulk metal 416 fills the entire feature 402 and includes an overburden. In the example shown, the bulk metal 416 overburden includes deposition on field areas 434 outside the feature 402 on the substrate surface.

At 450, an example patterned feature 402 is shown after the feature is planarized. The planarization step may remove materials outside the feature 402, including the initial metal nitride layer 408, the second metal nitride layer 414, and the bulk metal 416. The planarization step may be, for example, a chemical mechanical planarization (CMP).

In the embodiments depicted in FIGS. 3 and 4, deposition of bulk metal in the feature is performed without depositing a separate metal nucleation layer. The bulk metal is deposited directly on a gradient metal nitride layer and any exposed surfaces of the feature. The lower section of the feature is metal-rich and can serve as a nucleation layer for bulk fill in some embodiments.

A gradient metal nitride layer may have higher nitrogen at the top and less nitrogen each layer extends deeper into the feature. Thus, for example, a tungsten nitride layer may be characterized as having a composition WNₓ at a point near the feature opening and a composition WN_{y} at a point further in the feature, e.g., a mid-section or bottom portion of the feature, where x is greater than y. A molybdenum nitride layer may be similarly characterized. In the same or other embodiments, the thickness of the layer may be decreased with depth such that the total amount of nitrogen in the layer also decreases—with or without a composition change. In this manner, the inhibition effect of the nitrogen decreases with feature depth.

As noted above, in some embodiments, a feature includes two gradient metal nitride layers. The second gradient metal nitride layer may have less nitrogen than the first gradient metal nitride layer. This allows the second gradient metal nitride layer to effectively inhibit nucleation without a significant increase in resistivity. In some embodiments, the following sequence may be used to deposit two gradient metal nitride layers:
First gradient metal nitride layer: x times (B₂H₆/purge/WF₆/NH₃+WF₆)
Second gradient metal nitride layer: y times (B₂H₆/purge/WF₆/NH₃+WF₆)

The total amount of NH₃ in the first gradient metal nitride layer is higher than that in the second gradient metal nitride layer. Thus, one or more of dose time and flow rate of NH₃ may be decreased when transitioning from deposition of the first gradient metal nitride layer to the second

In some embodiments, a plasma-based process is used for one or both layers:
First gradient metal nitride layer: x times (B₂H₆/purge/WF₆/purge/N₂ plasma)
Second gradient metal nitride layer: y times (B₂H₆/purge/WF₆/purge/N₂ plasma)

The duration and/or N₂ flow rate of N₂ plasma is shorter in deposition of the second gradient metal nitride layer. gradient metal nitride layer. NH₃ may or may not be co-flowed with the metal precursor. In the above sequences, any appropriate metal precursor may be used instead of WF₆ and any appropriate reducing agent may be used instead of B₂H₆.

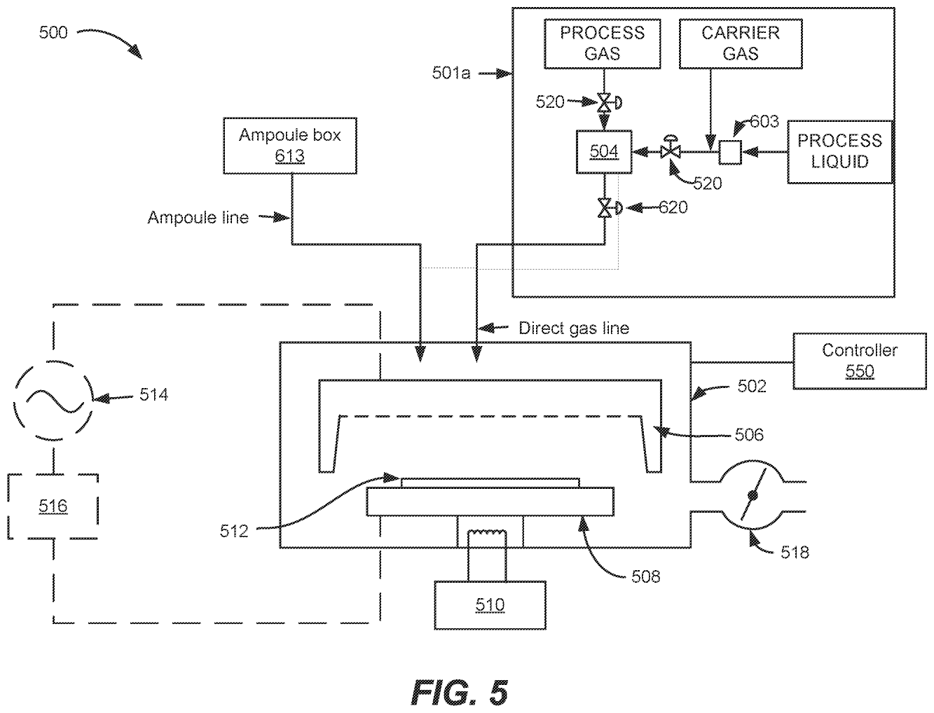

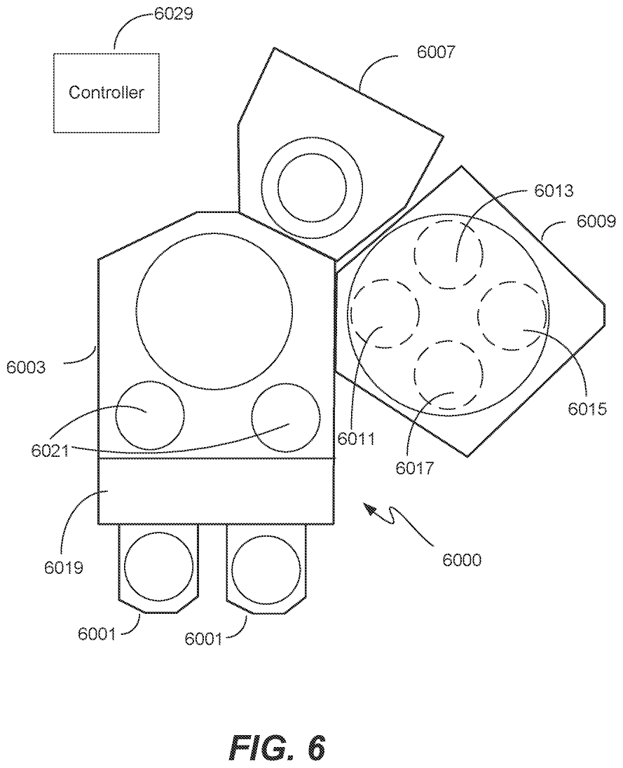

According to various embodiments, operations 103-109 and 303-307 may be performed in a single chamber or multiple chambers. If performed in multiple chambers, any two or more of the operations may be performed in a single chamber. A single station or multi-station chamber may be used. The operations may be performed in one or more stations. In some embodiments, the gradient metal liner and fill operations are performed in a single chamber. Employing the same metal precursors for both metal nitride and metal fill facilitates efficient use of a single chamber. Description of apparatus that may be used to implement the methods described herein is provided below with reference to FIGS. 5 and 6.

In the above discussion, examples of metal nucleation layer deposition, metal bulk deposition, metal nitride layer formation, and inhibition treatments are given. Further details of these processes are provided below and may be implemented in the methods as described above.

### Nucleation Layer Deposition

In some implementations, the methods described herein involve deposition of a metal nucleation layer prior to deposition of a bulk layer. A metal nucleation layer is a layer that facilitates subsequent deposition of bulk metal-containing material thereon. It is typically thin and conformal. According to various implementations, a metal nucleation layer may be deposited prior to any fill of the feature and/or at subsequent points during fill of the feature.

In certain implementations, the nucleation layer is deposited using a cyclical process of sequentially adding reactants for reaction in the feature. The may be an atomic layer deposition (ALD) process and/or a pulsed nucleation layer (PNL) technique. In such a technique, pulses of a reducing agent, optional purge gases, and metal-containing precursor are sequentially injected into and purged from the reaction chamber. The process is repeated in a cyclical fashion until the desired thickness is achieved. PNL techniques for depositing tungsten nucleation layers are described in U.S. Pat. Nos. 6,635,965; 7,005,372; 7,141,494; 7,589,017, 7,772,114, 7,955,972 and 8,058,170, and U.S. Patent Publication No. 2010-0267235, all of which are incorporated by reference herein in their entireties.

Nucleation layer thickness can depend on the nucleation layer deposition method as well as the desired quality of bulk deposition. In general, nucleation layer thickness is sufficient to support high quality, uniform bulk deposition. Examples may range from 5 Å-100 Å, e.g., 5 Å to 30 Å

In certain implementations, a bulk layer may be deposited directly in a feature without use of a nucleation layer. For example, in some implementations, the feature surface and/or an already-deposited under-layer supports bulk deposition.

Metal nucleation layer deposition can involve exposure to alternating pulses of a metal-containing precursor (also referred to as a metal precursor) and a reducing agent, separated by an inert purge gas. For tungsten deposition, examples of precursors include tungsten hexafluoride (WF₆). Chlorine-containing tungsten precursors (WClₓ) such as tungsten pentachloride (WCl₅) and tungsten hexachloride (WCl₆) may be used. These precursors may be reduced to elemental tungsten (W) by reaction with reducing agents such as silane (SiH₄) and diborane (B₂H₆).

In alternate embodiments, a metal precursor and a reducing agent may be co-flowed. If co-flowed, a sequence in which the metal precursor and reducing agent are co-flowed in pulses may be used. During the reactant doses, the metal precursor and reducing agent are co-flowed into the chamber. Co-flowing the reactants is more similar to a CVD reaction, which results in a higher deposition rate and rougher nucleation layer. Various modifications may be made to the sequence. For example, the metal precursor and reducing agent reactant pulses may be offset but overlap with a delay for one reactant with respect to the other. In another example, the inert gas may be pulsed for the purge phase.

Examples of reducing agents can include boron-containing reducing agents including B₂H₆ and other boranes, silicon-containing reducing agents including SiH₄ and other silanes, hydrazines, and germanes. In some implementations, pulses of tungsten-containing precursors can be alternated with pulses of one or more reducing agents, e.g., S/W/S/W/B/W, etc., where W represents a tungsten-containing precursor, S represents a silicon-containing precursor, and B represents a boron-containing precursor. In some implementations, a separate reducing agent may not be used, e.g., an organometallic tungsten-containing precursor may undergo thermal or plasma-assisted decomposition.

According to various implementations, hydrogen may or may not be run in the background. Further, in some implementations, deposition of a tungsten nucleation layer may be followed by one or more treatment operations prior to tungsten bulk deposition. Treating a deposited tungsten nucleation layer to lower resistivity is described for example in U.S. Pat. Nos. 7,772,114 and 8,058,170 and U.S. Patent Publication No. 2010-0267235, incorporated by reference herein.

While tungsten is described in various examples above, the methods may also be implemented with other metals and metal nitride layers including molybdenum (Mo) and molybdenum nitride (MoNₓ) where x is a number greater than 0.

Deposition of molybdenum (Mo) nucleation layers may be performed using Mo halide precursors or Mo oxyhalide precursors. Examples of Mo halide precursors include molybdenum dichloride (MoCl₂), molybdenum trichloride (MoCl₃), moly bdenum tetrachloride (MoCl₄), molybdenum pentachloride (MoCl₅), and molybdenum hexachloride (MoCl₆). In some embodiments, MoCl₅ or MoCl₆ are used. Further examples include molybdenum fluoride (MoF₆). Examples of molybdenum oxyhalides include molybdenum dichloride dioxide (MoO₂Cl₂), molybdenum tetrachloride oxide (MoOCl₄), molybdenum tetrafluoride oxide (MoOF₄), molybdenum dibromide dioxide (MoO₂Br₂), and the molybdenum iodides MoO₂I, and Mo₄O₁₁I.

In some embodiments, a nucleation layer may be deposited using a non-oxygen-containing precursor. Oxygen in oxygen-containing molybdenum precursors, for example, may react with a silicon- or boron-containing reducing agent to form MoSiₓO_{y} or MoBₓO_{y}, which are impure, high resistivity films. Oxygen-containing precursors may be used with oxygen incorporation minimized.

In some embodiments, the reducing agent pulses may be done at lower substrate temperatures than the Mo precursor pulses. For example, or B₂H₆ or a SiH₄ (or other boron- or silicon-containing reducing agent) pulse may be performed at a temperature below 300° C., with the Mo pulse at temperatures greater than 300° C.

### Bulk Deposition

Bulk deposition can occur by an ALD or CVD process. In a CVD process, a reducing agent and a metal precursor are co-flowed into a deposition chamber to deposit a bulk fill layer in the feature. An inert carrier gas may be used to deliver one or more of the reactant streams, which may or may not be pre-mixed. This operation generally involves flowing the reactants continuously until the desired amount is deposited. In certain implementations, the CVD operation may take place in multiple stages, with multiple periods of continuous and simultaneous flow of reactants separated by periods of one or more reactant flows diverted.

ALD deposition of a bulk layer involves exposure to alternating pulses of a metal-containing precursor and a reducing agent, separated by an inert purge gas, using the metal precursors described above with reference to nucleation layer deposition.

The same or different metal precursor used in nucleation layer deposition may be used for bulk deposition. In contrast to nucleation layer deposition in which a strong reducing agent such as diborane or silane may be used, hydrogen is often the reducing agent for bulk deposition.

Deposition may proceed according to various implementations until a certain feature profile is achieved and/or a certain amount of metal is deposited. In some implementations, the deposition time and other relevant parameters may be determined by modeling and/or trial and error. In some implementations, a process chamber may be equipped with various sensors to perform in-situ metrology measurements for end-point detection of a deposition operation. Examples of in-situ metrology include optical microscopy and X-Ray Fluorescence (XRF) for determining thickness of deposited films.

### Deposition of Metal Nitride

Depositing a metal nitride layer may be performed by exposing the feature to sequential pulses of a metal precursor (e.g., WF₆), a reducing agent and a nitriding in a thermal (non-plasma) or a plasma ALD process. In certain embodiments of a thermal process, diborane (B₂H₆) is used as the reducing agent and ammonia (NH₃) is the nitriding agent. Boron-containing reducing agents such as B₂H₆ may be used rather than silicon-containing reducing agents such as silane (SiH₄) as the latter can result in significantly long nucleation delay for tungsten nitride deposition. Another example of a suitable nitriding agent is N₂H₄. In some embodiments, NH₃ may be co-flowed with a metal precursor.

In certain embodiments in which deposition involves a fluorine-containing precursor such as WF₆ the ratio of the metal precursor to B₂H₆ is at least 2.9:1. High WF₆:B₂H₆ ratio reduces fluorine attack. The mechanism by which this occurs is by reducing the number of sites on the surface on which the reducing agent adsorbs, thereby reducing the number of sites where WF₆ will react. Thus, although there is more fluorine species in the deposition chamber, fewer will react near the surface. In some embodiments, the reducing agent may be diluted with an inert gas.

Example substrate temperature ranges for deposition include 250° C. to 400° C., e.g., 250° C. to 350° C. In some embodiments, a relatively low temperature is used to improve step coverage. In some embodiments, a WN surface may be dehalogenated after deposition. Dehalogenating the surface can involve exposing the surface to a plasma generated from a hydrogen-containing gas such as H₂. In some embodiments, the plasma is generated from an Ar/H₂ mixture or a N₂/H₂ mixture. H radicals in the plasma react with fluorine impurities to form HF gas, which can be exhausted from the processing chamber.

Deposition of a metal nitride involve plasma-enhanced deposition. In some embodiments, a remote or in-situ plasma generated from a nitrogen-containing gas such as N₂ may be used. Activated species such as atomic nitrogen or nitrogen ions may react with the metal precursor. According to various embodiments, one or more of the following sequences may be used to deposit a metal nitride layer.
B₂H₆ (or other reducing agent)/Metal precursor/NH₃
B₂H₆ (or other reducing agent)/Metal precursor/NH₃+metal precursor
B₂H₆ (or other reducing agent)/Metal precursor/N plasma species

In some embodiments, the reducing agent is ammonia (NH₃) or other nitrogen-containing reducing agent such hydrazine (N₂H₄). In such embodiments, the nitrogen-containing reducing agent may act as both a reducing agent and a nitridation agent. In such embodiments, the nitrogen-containing reducing agent may be co-flowed or pulsed with the metal precursor.

The amount of nitrogen in a metal nitride layer may vary. Accordingly, the term metal nitride (or tungsten nitride, molybdenum nitride, etc.) does not suggest a particular ratio of metal to nitrogen. Similarly, WN and MON may be used to indicate tungsten nitride and molybdenum nitride of any appropriate W:N or Mo:N ratio.

### Inhibition of Metal Nucleation

As described in U.S. patent application Ser. No. 13/774,350, incorporated by reference herein, selective inhibition can involve exposure to activated species that passivate the feature surfaces. For example, in certain implementations, a tungsten (W) surface or a molybdenum (Mo) can be passivated by exposure to a nitrogen-based or hydrogen-based plasma. In some implementations, inhibition can involve a chemical reaction between activated species and the feature surface to form a thin layer of a compound material such as tungsten nitride (WN) or tungsten carbide (WC). In some implementations, inhibition can involve a surface effect such as adsorption that passivates the surface without forming a layer of a compound material. Activated species may be formed by any appropriate method including by plasma generation and/or exposure to ultraviolet (UV) radiation. In some implementations, the substrate including the feature is exposed to a plasma generated from one or more gases fed into the chamber in which the substrate sits. In some implementations, one or more gases may be fed into a remote plasma generator, with activated species formed in the remote plasma generator fed into a chamber in which the substrate sits. The plasma source can be any type of source including radio frequency (RF) plasma source or microwave source. The plasma can be inductively and/or capacitively-coupled. Activated species can include atomic species, radical species, and ionic species. In certain implementations, exposure to a remotely-generated plasma includes exposure to radical and atomized species, with substantially no ionic species present in the plasma such that the inhibition process is not ion-mediated. In other implementations, ion species may be present in a remotely-generated plasma. In certain implementations, exposure to an in-situ plasma involves ion-mediated inhibition.

For tungsten (W) and molybdenum (Mo) surfaces, exposure to nitrogen-based and/or hydrogen-based plasmas inhibits subsequent deposition. Other chemistries that may be used for inhibition of these surfaces include oxygen-based plasmas and hydrocarbon-based plasmas. For example, molecular oxygen or methane may be introduced to a plasma generator. As used herein, a nitrogen-based plasma is a plasma in which the main non-inert component is nitrogen. An inert component such as argon, xenon, or krypton may be used as a carrier gas. In some implementations, no other non-inert components are present in the gas from which the plasma is generated except in trace amounts. In some implementations, inhibition chemistries may be nitrogen-containing, hydrogen-containing, oxygen-containing, and/or carbon-containing, with one or more additional reactive species present in the plasma.

In U.S. patent application Ser. No. 13/351,970, for example, nitridation of a feature surface to selectively passivate the surface is described. Using a NF₃ plasma, for example, where activated fluorine radicals react with and remove tungsten at the feature opening, the nitrogen generated from the NF₃ plasma can cause nitridation of the tungsten surface forming tungsten nitride. Subsequent deposition of tungsten on a nitrided surface is significantly delayed, compared to on a regular bulk tungsten film. A longer delay allows the feature to stay open for longer before pinching off. This improves fill because more WF₆ molecules can reach the inside of the feature and deposit tungsten. In addition to NF₃, fluorocarbons such as CF₄ or C₂F₈ may be used. However, in certain implementations, the inhibition species are fluorine-free to prevent etching during selective inhibition.

In certain implementations, UV radiation and/or thermal energy may be used instead of or in addition to plasma generators to provide activated species. In addition to tungsten surfaces, nucleation may be inhibited on liner/barrier layers surfaces such as TiN and/or WN surfaces. Any chemistry that passivates these surfaces may be used. For TiN and WN, this can include exposure to nitrogen-based or nitrogen-containing chemistries. In certain implementations, the chemistries described above for W may also be employed for TiN, WN, or other liner layer surfaces.

Tuning an inhibition profile can involve appropriately controlling an inhibition chemistry, substrate bias power, plasma power, process pressure, exposure time, and other process parameters. For in situ plasma processes (or other processes in which ionic species are present), a bias can be applied to the substrate. Substrate bias can, in some implementations, significantly affect an inhibition profile, with increasing bias power resulting in active species deeper within the feature. For 3-D structures in which selectivity is desired in a lateral direction (tungsten deposition preferred in the interior of the structure), but not in a vertical direction, increased bias power can be used to promote top-to-bottom deposition uniformity.

While bias power can be used in certain implementations as the primary or only knob to tune an inhibition profile for ionic species, in certain situations, other performing selective inhibition uses other parameters in addition to or instead of bias power. These include remotely generated non-ionic plasma processes and non-plasma processes. Also, in many systems, a substrate bias can be easily applied to tune selectivity in vertical but not lateral direction. Accordingly, for 3-D structures in which lateral selectivity is desired, parameters other than bias may be controlled, as described above.

Inhibition chemistry can also be used to tune an inhibition profile, with different ratios of active inhibiting species used. For example, for inhibition of W surfaces, nitrogen may have a stronger inhibiting effect than hydrogen; adjusting the ratio of N₂ and H₂ gas in a forming gas-based plasma can be used to tune a profile. The plasma power may also be used to tune an inhibition profile, with different ratios of active species tuned by plasma power. For example, in certain implementations described herein, nitrogen radical formation and resultant W—N formation and the related passivation effect can be modulated by varying the plasma power. Varying plasma power can also allow control of the resistivity of the final W film. For example, a remotely-generated plasma etch using NF₃ at low power may result in reduced nucleation delay (faster nucleation) in a subsequent deposition than a higher power remotely-generated plasma etch. This may be due to the presence of more nitrogen species during the high plasma power etch, increasing the formation of WN and the subsequent delay.

Process pressure can be used to tune a profile, as pressure can cause more recombination (deactivating active species) as well as pushing active species further into a feature. Process time may also be used to tune inhibition profiles, with increasing treatment time causing inhibition deeper into a feature.

In some implementations, selective inhibition can be achieved by in a mass transport limited regime. In this regime, the inhibition rate inside the feature is limited by amounts of and/or relative compositions of different inhibition material components (e.g., an initial inhibition species, activated inhibition species, and recombined inhibition species) that diffuse into the feature. In certain examples, inhibition rates depend on various components' concentrations at different locations inside the feature.

Mass transport limiting conditions may be characterized, in part, by overall inhibition concentration variations. In certain implementations, a concentration is less inside the feature than near its opening resulting in a higher inhibition rate near the opening than inside. This in turn leads to selective inhibition near the feature opening. Mass transport limiting process conditions may be achieved by supplying limited amounts of inhibition species into the processing chamber (e.g., use low inhibition gas flow rates relative to the cavity profile and dimensions), while maintaining relative high inhibition rates near the feature opening to consume some activated species as they diffuse into the feature. In certain implementation, a concentration gradient is substantial, which may be caused relatively high inhibition kinetics and relatively low inhibition supply. In certain implementations, an inhibition rate near the opening may also be mass transport limited, though this condition is not required to achieve selective inhibition.

In addition to the overall inhibition concentration variations inside features, selective inhibition may be influenced by relative concentrations of different inhibition species throughout the feature. These relative concentrations in turn can depend on relative dynamics of dissociation and recombination processes of the inhibition species. As described above, an initial inhibition material, such as molecular nitrogen, can be passed through a remote plasma generator and/or subjected to an in-situ plasma to generate activated species (e.g., atomic nitrogen, nitrogen ions). However, activated species may recombine into less active recombined species (e.g., nitrogen molecules) and/or react with W, WN, TiN, or other feature surfaces along their diffusion paths. As such, different parts of the feature may be exposed to different concentrations of different inhibition materials, e.g., an initial inhibition gas, activated inhibition species, and recombined inhibition species. This provides additional opportunities for controlling selective inhibition. For example, activated species are generally more reactive than initial inhibition gases and recombined inhibition species. Furthermore, in some cases, the activated species may be less sensitive to temperature variations than the recombined species. Therefore, process conditions may be controlled in such a way that removal is predominantly attributed to activated species. As noted above, some species may be more reactive than others. Furthermore, specific process conditions may result in activated species being present at higher concentrations near features' openings than inside the features. For example, some activated species may be consumed (e.g., reacted with feature surface materials and/or adsorbed on the surface) and/or recombined while diffusing deeper into the features, especially in small high aspect ratio features. Recombination of activated species can also occur outside of features, e.g., in the showerhead or the processing chamber, and can depends on chamber pressure. Therefore, chamber pressure may be specifically controlled to adjust concentrations of activated species at various points of the chamber and features.

Flow rates of the inhibition gas can depend on a size of the chamber, reaction rates, and other parameters. A flow rate can be selected in such a way that more inhibition material is concentrated near the opening than inside the feature.

In certain implementations, the substrate can be heated up or cooled down before selective inhibition. A predetermined temperature for the substrate can be selected to induce a chemical reaction between the feature surface and inhibition species and/or promote adsorption of the inhibition species, as well as to control the rate of the reaction or adsorption. For example, a temperature may be selected to have high reaction rate such that more inhibition occurs near the opening than inside the feature. Furthermore, a temperature may be also selected to control recombination of activated species (e.g., recombination of atomic nitrogen into molecular nitrogen) and/or control which species (e.g., activated or recombined species) contribute predominantly to inhibition. In certain implementations, a substrate is maintained at less than about 300° C., or more particularly at less than about 250° C., or less than about 150° C., or even less than about 100° C. In other implementations, a substrate is heated to between about 300° C. and 450° C. or, in more specific implementations, to between about 350° C. and 400° C. Other temperature ranges may be used for different types of inhibition chemistries. Exposure time can also be selected to cause selective inhibition. Example exposure times can range from about 10 s to 500 s, depending on desired selectivity and feature depth.

### Apparatus

FIG. 5 depicts a schematic illustration of an embodiment of an ALD process station 500 having a process chamber 502 for maintaining a low-pressure environment. In some embodiments, a plurality of ALD process stations may be included in a common low-pressure process tool environment. For example, FIG. 6 depicts an embodiment of a multi-station processing tool 500. In some embodiments, one or more hardware parameters of ALD process station 500, including those discussed in detail below, may be adjusted programmatically by one or more computer controllers 550. In some other embodiments, a process chamber may be a single station chamber.

ALD process station 500 fluidly communicates with reactant delivery system 501a for delivering process gases to a distribution showerhead 506. Reactant delivery system 601a includes a mixing vessel 504 for blending and/or conditioning process gases, such as a metal precursor gas, a hydrogen-containing gas, an argon or other carrier gas, or other reactant-containing gas, for delivery to showerhead 506. One or more mixing vessel inlet valves 520 may control introduction of process gases to mixing vessel 504. In various embodiments, deposition of an initial metal nitride gradient layer is performed in process station 500 and in some embodiments, other operations such as inhibition and/or metal gap fill may be performed in the same or another station of the multi-station processing tool 500 as further described below with respect to FIG. 6.

As an example, the embodiment of FIG. 5 includes a vaporization point 503 for vaporizing liquid reactant to be supplied to the mixing vessel 504. In some embodiments, vaporization point 503 may be a heated vaporizer. In some embodiments, a liquid precursor or liquid reactant may be vaporized at a liquid injector (not shown). For example, a liquid injector may inject pulses of a liquid reactant into a carrier gas stream upstream of the mixing vessel 604. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 503. In one scenario, a liquid injector may be mounted directly to mixing vessel 504. In another scenario, a liquid injector may be mounted directly to showerhead 506.

In some embodiments, a liquid flow controller (LFC) upstream of vaporization point 503 may be provided for controlling a mass flow of liquid for vaporization and delivery to process chamber 502. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 506 distributes process gases toward substrate 512. In the embodiment shown in FIG. 5, the substrate 512 is located beneath showerhead 506 and is shown resting on a pedestal 508. Showerhead 506 may have any suitable shape and may have any suitable number and arrangement of ports for distributing process gases to substrate 512.

In some embodiments, pedestal 508 may be raised or lowered to expose substrate 512 to a volume between the substrate 512 and the showerhead 506. In some embodiments, pedestal 508 may be temperature controlled via heater 510. Pedestal 508 may be set to any suitable temperature, such as between about 300° C. and about 500° C. during operations for performing various disclosed embodiments. It will be appreciated that, in some embodiments, pedestal height may be adjusted programmatically by a suitable computer controller 550. At the conclusion of a process phase, pedestal 508 may be lowered during another substrate transfer phase to allow removal of substrate 512 from pedestal 508.

In some embodiments, a position of showerhead 506 may be adjusted relative to pedestal 508 to vary a volume between the substrate 512 and the showerhead 506. Further, it will be appreciated that a vertical position of pedestal 508 and/or showerhead 506 may be varied by any suitable mechanism within the scope of the present disclosure. In some embodiments, pedestal 508 may include a rotational axis for rotating an orientation of substrate 512. It will be appreciated that, in some embodiments, one or more of these example adjustments may be performed programmatically by one or more suitable computer controllers 550. The computer controller 550 may include any of the features described below with respect to controller 6029 of FIG. 6.

In some embodiments where plasma may be used as discussed above, showerhead 506 and pedestal 508 electrically communicate with a radio frequency (RF) power supply 514 and matching network 516 for powering a plasma. In some embodiments, the plasma energy may be controlled by controlling one or more of a process station pressure, a gas concentration, an RF source power, an RF source frequency, and a plasma power pulse timing. For example, RF power supply 514 and matching network 516 may be operated at any suitable power to form a plasma having a desired composition of radical species. Likewise, RF power supply 514 may provide RF power of any suitable frequency. In some embodiments, RF power supply 514 may be configured to control high- and low-frequency RF power sources independently of one another. Example low-frequency RF frequencies may include, but are not limited to, frequencies between 0) kHz and 900 KHz. Example high-frequency RF frequencies may include, but are not limited to, frequencies between 1.8 MHZ and 2.45 GHZ, or greater than about 13.56 MHZ, or greater than 27 MHZ, or greater than 80 MHZ, or greater than 60 MHZ. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, a remote plasma generator is fluidically connected to showerhead 506. Gas may be fed to the remote plasma generator to generate plasma species, which can then be fed to the chamber 502.

In some embodiments, instructions for a controller 550) may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of an inert and/or a reactant gas (e.g., a metal precursor or ammonia), instructions for setting a flow rate of a carrier gas (such as argon), and time delay instructions for the first recipe phase. A second, subsequent recipe phase may include instructions for modulating or stopping a flow rate of an inert and/or a reactant gas, and instructions for modulating a flow rate of a carrier or purge gas and time delay instructions for the second recipe phase. A third recipe phase may include instructions for modulating a flow rate of a second reactant gas such as ammonia or nitrogen, instructions for modulating the flow rate of a carrier or purge gas, instructions for igniting a plasma, and time delay instructions for the third recipe phase. A fourth, subsequent recipe phase may include instructions for modulating or stopping a flow rate of an inert and/or a reactant gas, and instructions for modulating a flow rate of a carrier or purge gas and time delay instructions for the fourth recipe phase. It will be appreciated that these recipe phases may be further subdivided and/or iterated in any suitable way within the scope of the present disclosure.

Further, in some embodiments, pressure control for process station 500 may be provided by butterfly valve 518. As shown in the embodiment of FIG. 6, butterfly valve 518 throttles a vacuum provided by a downstream vacuum pump (not shown). However, in some embodiments, pressure control of process station 600 may also be adjusted by varying a flow rate of one or more gases introduced to the process station 600.

FIG. 6 is a schematic of a process system suitable for conducting deposition processes in accordance with embodiments. The system 6000 includes a transfer module 6003. The transfer module 6003 provides a clean, pressurized environment to minimize risk of contamination of substrates being processed as they are moved between various reactor modules. Mounted on the transfer module 6003 is a multi-station reactor 6009 capable of performing ALD, treatment, and CVD according to various embodiments. Multi-station reactor 6009 may include multiple stations 6011, 6013, 6015, and 6017 that may sequentially perform operations in accordance with disclosed embodiments. For example, multi-station reactor 6009 may be configured such that station 6011 performs a tungsten nucleation layer deposition using a tungsten precursor and a boron- or silicon-containing reducing agent, station 6013 performs an ALD deposition of a gradient metal nitride layer, station 6015 performs an inhibition treatment operation or deposition of a second gradient metal nitride layer, and station 6017 may perform a bulk ALD fill after treatment using H₂ as reducing agent.

Stations may include a heated pedestal or substrate support, one or more gas inlets or showerhead or dispersion plate.

Returning to FIG. 6, also mounted on the transfer module 6003 may be one or more single or multi-station modules 6007 capable of performing plasma or chemical (non-plasma) pre-cleans, other deposition operations, or etch operations. The module may also be used for various treatments to, for example, prepare a substrate for a deposition process. The system 6000 also includes one or more wafer source modules 6006, where wafers are stored before and after processing. An atmospheric robot (not shown) in the atmospheric transfer chamber 6019 may first remove wafers from the source modules 6001 to loadlocks 6021. A wafer transfer device (generally a robot arm unit) in the transfer module 6003 moves the wafers from loadlocks 6021 to and among the modules mounted on the transfer module 6003.

In various embodiments, a system controller 6029 is employed to control process conditions during deposition. The controller 6029 will typically include one or more memory devices and one or more processors. A processor may include a CPU or computer, analog and/or digital input/output connections, stepper motor controller boards, etc.

The controller 6029 may control all of the activities of the deposition apparatus. The system controller 6029 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 1029 may be employed in some embodiments.

Typically there will be a user interface associated with the controller 6029. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general-purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the system controller 6029. The signals for controlling the process are output on the analog and digital output connections of the apparatus.

The system software may be designed or configured in many different ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a controller 6029 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 1029, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 6029, in some implementations, may be a part of or coupled to a computer that is integrated with, coupled to the system, otherwise networked to the system, or a combination thereof. For example, the controller 6029 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller 6029 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool: (2) curing of photoresist using a hot plate or furnace or UV curing tool: (3) exposing the photoresist to visible or UV or x-ray light with a tool such as a wafer stepper: (4) developing the resist so as to selectively remove resist and thereby pattern it using a tool such as a wet bench: (5) transferring the resist pattern into an underlying film or workpiece by using a dry or plasma-assisted etching tool; and (6) removing the resist using a tool such as an RF or microwave plasma resist stripper.

What is claimed is:

1. A method comprising:
providing a substrate comprising a feature having a feature opening, a feature bottom and feature sidewalls; and
non-conformally depositing a metal nitride layer in the feature such that the metal nitride layer lines at least part of the feature sidewalls and decreases in thickness and/or nitrogen concentration along the feature sidewalls as the metal nitride layer extends from the feature opening towards the feature bottom.

2. The method of claim 1, further comprising after depositing the metal nitride layer, depositing a metal nucleation layer in the feature.

3. The method of claim 2, further comprising non-conformally treating the metal nucleation layer to inhibit metal nucleation, wherein metal nucleation on the feature sidewalls is inhibited to greater extent near the feature opening than near the feature bottom.

4. The method of claim 2, further comprising depositing a bulk metal layer on the metal nucleation layer.

5. The method of claim 1, wherein the metal is tungsten or molybdenum.

6. The method of claim 1, wherein non-conformally depositing the metal nitride layer in the feature comprises delivering pulses of ammonia (NH₃) and a metal-containing precursor to a chamber housing the substrate.

7. The method of claim 6, wherein non-conformally depositing the metal nitride in the feature further comprises delivering pulses of diborane (B₂H₆) to the chamber.

8. The method of claim 1, wherein non-conformally depositing the metal nitride in the feature comprises delivering pulses of a metal-containing precursor and plasma-activated nitrogen species to a chamber housing the substrate.

9. The method of claim 8, wherein non-conformally depositing the metal nitride in the feature further comprises delivering pulses of diborane (B₂H₆) to the chamber.

10. The method of claim 1, wherein the thickness of the metal nitride layer on the sidewall near the feature opening is at least twice the thickness of the metal nitride layer on the sidewall at a point halfway down the sidewall between the feature opening and the feature bottom.

11. The method of claim 1, wherein the thickness of the metal nitride layer at its thickest point is between 20 and 100 angstroms.

12. The method of claim 3, wherein the non-conformal treatment forms a second metal nitride layer.

13. The method of claim 12, wherein the thickness of the second metal nitride layer at its thickest point is less than 10 angstroms.

14. The method of claim 1, further comprising non-conformally treating the metal nitride barrier layer to inhibit metal nucleation such that metal nucleation is inhibited to a greater extent near the feature opening than further in the feature.

15. The method of claim 14, wherein the non-conformal treatment forms a second metal nitride layer.

16. The method of claim 15, wherein the second metal nitride layer decreases in amount of nitride as the second metal nitride layer extends from the feature opening towards the feature bottom and the amount of nitride in the second metal nitride layer is less than the amount of nitride in the metal nitride barrier layer.

17. The method of claim 1, further comprising depositing a bulk metal layer in the feature including directly on a metal nitride layer.

18. The method of claim 14, wherein non-conformally treating the metal nitride barrier layer to inhibit metal nucleation comprises delivering pulses of ammonia and a metal-containing precursor to the chamber.

19. The method of claim 18, wherein non-conformally treating the metal nitride barrier layer in the feature further comprises delivering pulses of diborane to the chamber.

20. The method of claim 18, wherein a ratio of ammonia to the metal-containing precursor is higher in the deposition of the metal nitride barrier layer than a ratio of ammonia to the metal-containing precursor in the non-conformal treatment of the metal nitride barrier layer.

21. The method of claim 14, wherein non-conformally depositing the metal nitride barrier layer in the feature comprises delivering pulses of a metal-containing precursor and a plasma-activated nitrogen species to a chamber housing the substrate.

22. The method of claim 21, wherein non-conformally depositing the metal nitride barrier layer in the feature further comprises delivering pulses of diborane to the chamber.

23. The method of claim 21, wherein non-conformally treating the metal nitride barrier layer to inhibit metal nucleation comprises delivering pulses of a metal-containing precursor and a plasma-activated nitrogen species to the chamber.

24. A method comprising:
providing a feature;
performing a first operation of exposing the feature to pulses of a metal precursor, a boron-containing reducing agent, and a nitrogen-containing compound;
performing a second operation of exposing the feature to pulses of a metal precursor, a boron-containing reducing agent, and a nitrogen-containing compound, wherein the amount of nitrogen is higher in the first operation than the second operation; and
after the first operation and the second operation, exposing the feature to the metal precursor and hydrogen.
